(19) United States
(12) Patent Application Publication
(10) Pub. No.: US 2018/0178492 A1
(43) Pub. Date: Jun. 28, 2018

(54) LAMINATE, SILICONE RESIN LAYER-ATTACHED SUPPORT SUBSTRATE, SILICONE RESIN LAYER-ATTACHED RESIN SUBSTRATE, AND METHOD FOR PRODUCING ELECTRONIC DEVICE

(71) Applicant: Asahi Glass Company, Limited, Chiyoda-ku (JP)

(72) Inventors: Yohei Nagao, Tokyo (JP); Kazuo Yamada, Tokyo (JP); Masaru Yamauchi, Tokyo (JP); Hirotoshi Terui, Tokyo (JP)

(73) Assignee: Asahi Glass Company, Limited, Chiyoda-ku (JP)

(21) Appl. No.: 15/856,343

(22) Filed: Dec. 28, 2017

(30) Foreign Application Priority Data
Dec. 28, 2016 (JP) 2016-255155
Jun. 20, 2017 (JP) 2017-120816
Sep. 27, 2017 (JP) 2017-186225

(51) Int. Cl. B32B 17/06; B32B 37/14; B32B 38/10; B32B 27/28

(52) U.S. Cl. CPC B32B 17/064; B32B 37/14; B32B 38/10; H01L 51/56; B32B 2457/14; B32B 2457/206; B32B 27/281

(57) ABSTRACT

The present invention provides a laminate including a support substrate, a silicone resin layer and a substrate arranged in this order, in which the silicone resin layer contains at least one metal element selected from the group consisting of 3d transition metals, 4d transition metals, lanthanide metals, and bismuth and in which end portion degradation of a silicone resin layer is suppressed.

### FIELD OF THE INVENTION

The present invention relates to a laminate, a silicone resin layer-attached support substrate, a silicone resin layer-attached resin substrate, and a method for producing an electronic device.

### BACKGROUND OF THE INVENTION

In recent years, devices (electronic devices) such as photovoltaic cells (PV), liquid crystal display (LCD) panels, organic EL display (OLED) panels, and receiving sensor panels for detecting electromagnetic waves, X-rays, ultraviolet rays, visible rays, infrared rays, etc. are becoming thinner and lighter, and substrates represented by glass substrates used for these devices are being made thinner. When the strength of the glass substrate is insufficient due to the thinning, handleability of the substrate is deteriorated in the device manufacturing steps.

Recently, in order to cope with the problem described above, a method has been proposed, in which a glass laminate including a glass substrate and a reinforcing plate laminated thereon is prepared, a member for an electronic device such as a display device is formed on the glass substrate of the glass laminate, and thereafter the reinforcing plate is separated from the glass substrate (for example, Patent Document 1). The reinforcing plate has a support plate and a silicone resin layer fixed onto the support plate, and the silicone resin layer and the glass substrate are made to peelably adhere to each other in the glass laminate.

Patent Document 1: WO 2007/018028

### SUMMARY OF THE INVENTION

In recent years, as an electronic device member is provided with higher functions or more complicated, it is demanded to perform heating treatment under an air atmosphere and in a higher temperature condition (for example, 450° C.) when the member for the electronic device, such as an oxide semiconductor, is formed.

The present inventors prepared a glass laminate according to the Patent Document 1 and performed heating treatment in the aforementioned conditions. As a result, the inventors found that a silicone resin layer in the glass laminate is whitened and degraded in the vicinity of its end portion (such degradation will be also referred to as “end portion degradation”). Specifically, as shown in FIG. 3 which is a top view of a glass laminate subjected to heating treatment, degradation occurs in an end portion 102 of a silicone resin layer of a glass laminate 100. When a gap is generated in the vicinity of the end portion of the silicone resin layer due to the end portion degradation, there may occur a problem in process such as a problem that an agent used in a wet step may intrude into the glass laminate to pollute an apparatus for a vacuum process performed thereafter, or a problem that the agent used in preceding step may be mixed into an agent used in another wet step performed subsequently.

In consideration of the aforementioned situation, the present invention provides a laminate in which end portion degradation of a silicone resin layer is suppressed.

In addition, the invention provides a silicone resin layer-attached support substrate, a silicone resin layer-attached resin substrate, and a method for manufacturing an electronic device, which can be each applied to the aforementioned laminate.

As a result of intensive studies to solve the problem described above, the present inventors found that the problem can be solved by the following configurations.

[1] A laminate including a support substrate, a silicone resin layer; and a substrate arranged in this order, in which the silicone resin layer contains at least one metal element selected from the group consisting of 3d transition metals, 4d transition metals, lanthanide metals, and bismuth.

[2] The laminate according to [1], in which the silicone resin layer contains at least one metal element selected from the group consisting of 3d transition metals, lanthanide metals, and bismuth.

[3] The laminate according to [1] or [2], in which the silicone resin layer contains at least one metal element selected from the group consisting of iron, manganese, copper, cerium, cobalt, nickel, chromium, and bismuth.

[4] The laminate according to any one of [1] to [3], in which the silicone resin layer contains at least one metal element selected from the group consisting of iron, manganese, copper, cerium, and bismuth.

[5] The laminate according to any one of [1] to [4], in which a plurality of the substrates are laminated on the support substrate through the silicone resin layer.

[6] The laminate according to any one of [1] to [5], in which the substrate is a glass substrate.

[7] The laminate according to any one of [1] to [5], in which the substrate is a resin substrate.

[8] The laminate according to [7], in which the resin substrate is a polyimide resin substrate.

[9] The laminate according to any one of [1] to [5], in which the substrate is a substrate containing a semiconductor material.

[10] The laminate according to [9], in which the semiconductor material is Si, SiC, GaN, gallium oxide or diamond.

[11] A silicone resin layer-attached support substrate, including: a support substrate, and a silicone resin layer arranged in this order, in which the silicone resin layer contains at least one metal element selected from the group consisting of 3d transition metals, 4d transition metals, lanthanide metals, and bismuth.

[12] A method for manufacturing an electronic device, including: a member forming step of forming an electronic device member on a surface of the substrate of the laminate according to any one of claims 1 to 10, to obtain an electronic device member-attached laminate; and a separation step of removing the silicone resin layer-attached support substrate which includes the support substrate and the silicone resin layer, from the electronic device member-attached laminate, to obtain an electronic device including the substrate and the electronic device member.

[13] A silicone rein layer-attached resin substrate, including: a resin substrate, and a silicone resin layer arranged in this order, in which the silicone resin layer contains at least one metal element selected from the group consisting of 3d transition metals, 4d transition metals, lanthanide metals, and bismuth.

[14] A method for manufacturing an electronic device, including: a step of forming a laminate using the silicone resin layer-attached resin substrate according to claim 13, and a support substrate; a member forming step of forming an electronic device member on a surface of the resin substrate of the laminate, to obtain an electronic device member-attached laminate; and a separation step of removing the support substrate and the silicone resin layer from the electronic device member-attached laminate, to obtain an electronic device including the resin substrate and the electronic device member.

According to the present invention, it is possible to provide a laminate in which end portion degradation of a silicone resin layer is suppressed.

In addition, according to the invention, it is possible to provide a silicone resin layer-attached support substrate, a silicone resin layer-attached resin substrate, and a method for manufacturing an electronic device, which can be each applied to the aforementioned laminate.

### BRIEF DESCRIPTION OF THE DRAWINGS

FIG. 1 is a schematic sectional view of an embodiment of a glass laminate according to the invention.

FIG. 2A and FIG. 2B are schematic sectional views showing, step by step, an embodiment of a method for manufacturing an electronic device according to the invention.

FIG. 3 is a top view showing a state in which end portion degradation has occurred in a laminate according to the background art.

### DETAILED DESCRIPTION OF THE INVENTION

An embodiment for carrying out the invention will be described below with reference to the drawings. However, the invention is not limited to the following embodiment. Various modifications and substitutions can be performed on the following embodiment without departing from the scope of the present invention.

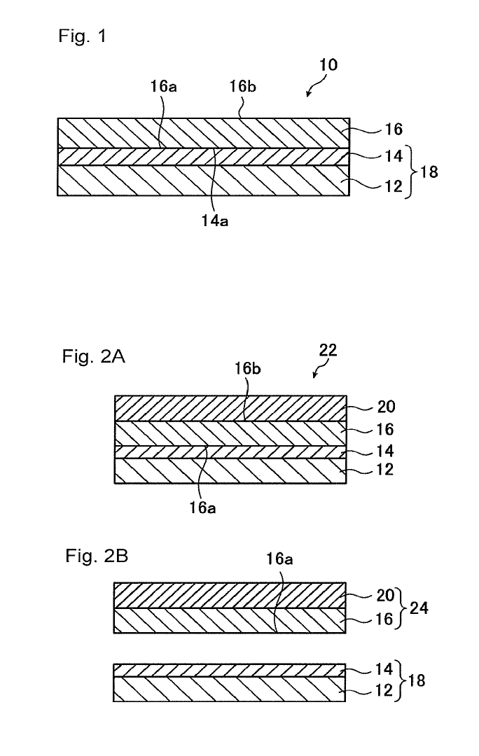

FIG. 1 is a schematic cross-sectional view of an embodiment of a glass laminate which is one mode of a laminate according to the present invention.

As illustrated in FIG. 1, a glass laminate 10 is a laminate which includes a support substrate 12, a glass substrate 16, and a silicone resin layer 14 disposed between those substrates. One surface of the silicone resin layer 14 is in contact with the support substrate 12 and the other surface thereof is in contact with a first main surface 16a of the glass substrate 16.

In the glass laminate 10, a peel strength between the silicone resin layer 14 and the glass substrate 16 is lower than a peel strength between the silicone resin layer 14 and the support substrate 12. Therefore, the silicone resin layer 14 is peeled from the glass substrate 16 to separate the glass substrate 16 from a laminate of the silicone resin layer 14 and the support substrate 12. To say other words, the silicone resin layer 14 is fixed onto the support substrate 12, and the glass substrate 16 is peelably laminated onto the silicone resin layer 14.

The two-layer portion formed of the support substrate 12 and the silicone resin layer 14 has a function of reinforcing the glass substrate 16. Here, the two-layer portion containing the support substrate 12 and the silicone resin layer 14, which is manufactured in advance for manufacturing the glass laminate 10, is referred to as a silicone resin layer-attached support substrate 18.

The glass laminate 10 is separated into the glass substrate 16 and the silicone resin layer-attached support substrate 18 by a procedure which will be described later. The silicone resin layer-attached support substrate 18 is laminated to a new glass substrate 16 and can be reused as a new glass laminate 10.

The peel strength between the support substrate 12 and the silicone resin layer 14 is a peel strength (x). When a stress in a peeling direction exceeding the peel strength (x) is applied between the support substrate 12 and the silicone resin layer 14, the support substrate 12 and the silicone resin layer 14 are peeled from each other. The peel strength between the silicone resin layer 14 and the glass substrate 16 is a peel strength (y). When a stress in a peeling direction exceeding the peel strength (y) is applied between the silicone resin layer 14 and the glass substrate 16, the silicone resin layer 14 and the glass substrate 16 are peeled from each other.

In the glass laminate 10, the peel strength (x) is higher than the peel strength (y). Accordingly, when a stress is applied to the glass laminate 10 in a direction for peeling the support substrate 12 and the glass substrate 16 from each other, the glass laminate 10 is peeled between the silicone resin layer 14 and the glass substrate 16, and separated into the glass substrate 16 and the silicone resin layer-attached support substrate 18.

The peel strength (x) is preferably much higher than the peel strength (y).

In order to increase an adhesion force of the silicone resin layer 14 to the support substrate 12, it is preferable that curable silicone resin which will be described later is cured on the support substrate 12 to form the silicone resin layer 14. Due to the adhesion force generated upon curing, it is possible to form the silicone resin layer 14 bonded to the support substrate 12 with a high bonding force.

Meanwhile, the bonding force of the cured silicone resin to the glass substrate 16 is typically lower than the aforementioned bonding force generated upon curing. Accordingly, when the silicone resin layer 14 is formed on the support substrate 12 and then the glass substrate 16 is laminated on the surface of the silicone resin layer 14, it is possible to manufacture the glass laminate 10.

First, detailed description will be made below about each layer (the support substrate 12, the glass substrate 16 and the silicone resin layer 14) constituting the glass laminate 10. After that, detailed description will be made about the method for manufacturing the glass laminate.

### <Support Substrate>

The support substrate 12 is a member for supporting and reinforcing the glass substrate 16.

As the support substrate 12, for example, a glass sheet, a plastic sheet, a metal sheet (such as a SUS sheet), or the like is used. Generally, the support substrate 12 is preferably formed of a material having a small difference in linear expansion coefficient with respect to the glass substrate 16. More preferably, the support substrate 12 is formed of the same material as the glass substrate 16. In particular, the support substrate 12 is preferably a glass sheet made of the same glass material as the glass substrate 16.

The thickness of the support substrate 12 may be thicker than that of the glass substrate 16 or may be thinner than that of the glass substrate 16. The thickness of the support substrate 12 is preferably thicker than that of the glass substrate 16, from the viewpoint of handleability of the glass laminate 10.

When the support substrate 12 is a glass sheet, the thickness of the glass sheet is preferably 0.03 mm or more in order to make it easy to handle the glass sheet and to prevent the glass sheet from cracking. In addition, the thickness of the glass sheet is preferably 1.0 mm or less in order to obtain rigidity with which the glass sheet can be bent moderately without cracking when the glass substrate is peeled.

The difference in average linear expansion coefficient at 25 to 300° C. between the support substrate 12 and the glass substrate 16 is preferably 10×10⁻⁷/C or less, more preferably 3×10⁻⁷/° C. or less, and further more preferably 1×10⁻⁷/C or less.

### <Glass Substrate>

The type of the glass of the glass substrate 16 is not particularly limited, but an oxide-based glass containing silicon oxide as its main component, such as alkali-free borosilicate glass, borosilicate glass, soda-lime glass, high silica glass, or the like is preferable. As the oxide-based glass, a glass having a silicon oxide content of 40 to 90 mass % in terms of oxide is preferable.

As for the glass substrate 16, more specifically, a glass sheet (AN100 manufactured by Asahi Glass Co., Ltd.) made of alkali-free borosilicate glass can be used as a glass substrate for a display apparatus such as an LCD or an OLED or a glass substrate for a sensor panel for receiving electromagnetic waves, X-rays, ultraviolet rays, visible rays, infrared rays, etc.

From the viewpoint of reduction in thickness and/or reduction in weight, the thickness of the glass substrate 16 is preferably 0.5 mm or less, more preferably 0.4 mm or less, further more preferably 0.2 mm or less, and particularly preferably 0.10 mm or less. When the thickness is 0.5 mm or less, it is possible to impart favorable flexibility to the glass substrate 16. When the thickness is 0.2 mm or less, it is possible to wind the glass substrate 16 into a roll shape.

In addition, the thickness of the glass substrate 16 is preferably 0.03 mm or more for ease of handling the glass substrate 16.

Further, the area (the area of the main surface) of the glass substrate 16 is not particularly limited, but the area is preferably 300 cm² or more.

The glass substrate 16 may consist of two or more layers. In this case, the layers may be made of one and the same kind of material, or may be made of different kinds of materials respectively. In this case, the “thickness of the glass substrate 16” means the total thickness of all the layers.

The method for manufacturing the glass substrate 16 is not particularly limited. The glass substrate 16 is typically obtained by melting a glass raw material and forming the molten glass into a sheet shape. Such a forming method may be a general one and, for example, a float process, a fusion process, a slot down draw process, or the like may be used.

### <Silicone Resin Layer>

The silicone resin layer 14 prevents a positional displacement of the glass substrate 16 and prevents the glass substrate 16 from being damaged by the separation operation. A surface 14a of the silicone resin layer 14 in contact with the glass substrate 16 adheres to the first main surface 16a of the glass substrate 16.

It is considered that the silicone resin layer 14 and the glass substrate 16 are bonded to each other with weak adhesion force or a bonding force due to van der Waals force.

In addition, the silicone resin layer 14 is bonded to the surface of the support substrate 12 with a strong bonding force. A known method may be used as a method for enhancing the adhesion between the both. For example, as described below, the silicone resin layer 14 is formed on the surface of the support substrate 12 (more specifically, a curable silicone (organo-polysiloxane) capable of forming a predetermined silicone resin is cured on the support substrate 12) so that the silicone resin in the silicone resin layer 14 can be bonded to the surface of the support substrate 12 to thereby obtain a high bonding force. In addition, it is also possible to carry out a treatment (for example, a treatment using a coupling agent) for generating a strong bonding force between the surface of the support substrate 12 and the silicone resin layer 14 to increase the bonding force between the surface of the support substrate 12 and the silicone resin layer 14.

Although the thickness of the silicone resin layer 14 is not particularly limited, it is preferably 100 μm or less, more preferably 50 μm or less, and further more preferably 10 μm or less. The lower limit of the thickness is not particularly limited, but is often set at 0.001 μm or more. When the thickness of the silicone resin layer 14 is in such a range, it is possible to suppress the occurrence of cracks onto the silicone resin layer 14 and the occurrence of distortion defects in the glass substrate 16 even if bubbles or a foreign substance are interposed between the silicone resin layer 14 and the glass substrate 16.

The aforementioned thickness is intended to be an average thickness, which is obtained by arithmetic averaging values of the thickness of the silicone resin layer 14 measured at any five or more positions by a contact-type film thickness measuring apparatus.

Surface roughness Ra in a surface of the silicone resin layer 14 on the glass substrate 16 side is not particularly limited, but it is preferably 0.1 to 20 nm and more preferably 0.1 to 10 nm because of more excellent laminating property and peelability of the glass substrate 16.

Here, a method for measuring the surface roughness Ra is performed according to JIS B 0601-2001, values of Ra measured at any five or more places are arithmetically averaged, and the value thus obtained corresponds to the aforementioned surface roughness Ra.

The silicone resin layer contains at least one metal element selected from the group consisting of 3d transition metals, 4d transition metals, lanthanide metals, and bismuth (Bi) (hereinafter referred to as “specified element” collectively). When the specified element is contained, the end portion degradation of the silicone resin layer is suppressed during heating treatment at a high temperature under an air atmosphere. The details of the reason are unknown, but it is considered that oxidation of the silicone resin is suppressed due to the specified element contained in the silicone resin layer.

The 3d transition metals include transition metals of the fourth period of the periodic table, that is, metals from scandium (Sc) to copper (Cu). Specifically, scandium (Sc), titanium (Ti), vanadium (V), chromium (Cr), manganese (Mn), iron (Fe), cobalt (Co), nickel (Ni), and copper (Cu) are included.

The 4d transition metals include transition metals of the fifth period of the periodic table, that is, metals from yttrium (Y) to silver (Ag). Specifically, yttrium (Y), zirconium (Zr), niobium (Nb), molybdenum (Mo), technetium (Tc), ruthenium (Ru), rhodium (Rh), palladium (Pd), and silver (Ag) are included.

The lanthanide metals include metals from lanthanum (La) to lutetium (Lu). Specifically, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu) are included.

Among them, in order to more suppress the end portion degradation of the silicone resin layer, the silicone resin layer preferably contains at least one metal element selected from the group consisting of the 3d transition metals, the lanthanide metals, and bismuth (Bi), more preferably contains at least one metal element selected from the group consisting of iron, manganese, copper, cerium, cobalt, nickel, chromium, and bismuth, further more preferably contains at least one metal element selected from the group consisting of iron, manganese, copper, cerium, chromium, and cobalt, and particularly preferably contains at least one metal element selected from the group consisting of iron, manganese, copper, cerium, and bismuth.

Here, the silicone resin layer may contain one kind of the aforementioned specified elements, or may contain two or more kinds of the specified elements.

The content of the specified element in the silicone resin layer is not particularly limited. However, in order to more suppress the end portion degradation of the silicone resin layer, the content is preferably 0.001 part by mass or more and more preferably 0.01 part by mass or more in 100 parts by mass of the silicone resin layer. The upper limit value of the content of the specified element in the silicone resin layer is not particularly limited, but it is preferably 1.0 part by mass or less and more preferably 0.7 parts by mass or less.

When the silicone resin layer contains two or more kinds of the specified elements, it is preferable that the total content of them is within the aforementioned range.

The optimum content of the specified element is selected according to the kind of the metal.

In addition, when the silicone resin layer contains at least one metal element selected from the group consisting of the 3d transition metals, the lanthanide metals, and bismuth (Bi) (hereinafter referred to as “preferred specified element” collectively), the content of the preferred specified element in the silicone resin layer is not particularly limited. However, in order to more suppress the end portion degradation of the silicone resin layer, the content is preferably 0.01 part by mass or more and more preferably 0.03 parts by mass or more in 100 parts by mass of the silicone resin layer. The upper limit value of the content of the preferred specified element in the silicone resin layer is not particularly limited, but it is preferably 0.7 parts by mass or less and more preferably 0.5 parts by mass or less.

When the silicone resin layer contains two or more kinds of the preferred specified elements, it is preferable that the total content of them is within the aforementioned range.

The silicone resin layer may contain other metal elements (such as a tin element, an aluminum element, and a platinum element) than the aforementioned specified elements.

In addition, the silicone resin layer may contain a curing catalyst for promoting a condensation reaction or a curing catalyst for promoting an addition reaction. The curing catalyst for promoting a condensation reaction includes an aluminum chelate compound such as aluminum trisacetylacetonate or aluminum trisethylacetoacetate, a tin compound such as dibutyltin dilaurate or bis (2-ethylhexanoate) tin(II). The curing catalyst for promoting an addition reaction includes a platinum-based catalyst.

When the silicone resin layer contains a tin element, peel strength for the glass substrate disposed on the silicone resin layer is apt to deteriorate, so that the glass substrate can be peeled easily. In addition, from the viewpoint of balance between the heat resistance of the silicone resin layer and the peelability of the substrate, the tine element is preferably used together with a zirconium element. That is, when the silicone resin layer contains a tin element, it is preferable that the silicone resin layer also contains a zirconium element.

In addition, when the silicone resin layer contains an aluminum element, the heat resistance of the silicone resin layer can be improved easily.

The aforementioned specified elements and the aforementioned other metal elements may be in any of a metal form, an ion form, a compound form and a complex form in the silicone resin layer.

A method for measuring the aforementioned specified elements and the aforementioned other metal elements in the silicone resin layer is not particularly limited, but a known method may be used. For example, an ICP atomic emission spectroscopy (ICP-AES) analysis method or an ICP mass spectrometry (ICP-MS) analysis method may be used. Examples of apparatus for use in the aforementioned method include an inductively coupled plasma emission spectrophotometer PS3520UVDDII (Hitachi High-Technologies Corporation), and an inductively coupled plasma (triple quadrupole) mass spectrometer Agilent8800 (Agilent Technologies).

A specific example of a procedure using the aforementioned method will be described. First, the mass of the silicone resin layer is measured. Next, the silicone resin layer is oxidized and formed into silica by use of an oxygen burner or the like. After that, the oxidized silicone resin layer is cleansed by hydrofluoric acid to remove a SiO₂ component from the oxidized silicone resin layer. A residue thus obtained is dissolved in hydrochloric acid, and predetermined specified elements and/or other metal elements are quantitatively determined by the aforementioned ICP atomic emission spectroscopy (ICP-AES) analysis method or the ICP mass spectrometry (ICP-MS) analysis method. After that, the contents of the specified elements and the other metal elements are calculated relative to the mass of the silicone resin layer measured in advance.

The method for forming the silicone resin layer containing the specified element is not particularly limited. A method in which the silicone resin layer is formed by use of a curable composition containing curable silicone and a metal compound containing the specified element may be used. The method will be described later.

In addition, as a method for introducing the other metal elements into the silicone resin layer, a method in which the silicone resin layer is formed by use of the aforementioned curable composition containing curable silicone, which will be described later, a metal compound containing the specified element, and a metal compound containing the other metal elements may be used in the same manner as the aforementioned specified element.

The details will be described later.

### (Silicone Resin)

The silicone resin layer 14 is mainly made of silicone resin.

Generally, organosiloxy units include a monofunctional organosiloxy unit called an M unit, a difunctional organosiloxy unit called a D unit, a trifunctional organosiloxy unit called a T unit, and a quadfunctional organosiloxy unit called a Q unit. The Q unit is a unit having no organic group bonded to a silicon atom (no organic group having a carbon atom bonded to a silicon atom), but it is regarded as an organosiloxy unit (a unit containing a silicon bond) in the present invention. Monomers forming the M unit, the D unit, the T unit and the Q unit are also referred to as an M monomer, a D monomer, a T monomer and a Q monomer respectively.

Total organosiloxy units means a total of M units, D units, T units and Q units. The ratio of numbers (molar quantities) among the M units, the D units, the T units and the Q units can be calculated from a value of a peak area ratio based on ²⁹Si-NMR.

Any organosiloxy unit has a siloxane bond in which two silicon atoms are bonded via one oxygen atom. Accordingly, the number of oxygen atoms per one silicon atom in the siloxane bond is regarded as ½, and is expressed as O_{1/2} in a formula. More specifically, for example, in one D unit, one silicon atom is bonded to two oxygen atoms, and each of the oxygen atoms is bonded to silicon atoms of other units. Accordingly, the D unit is expressed by a formula of —O_{1/2}—(R)₂Si—O_{1/2}— (R represents a hydrogen atom or an organic group). Since there are two O_{1/2}, the D unit is typically expressed as (R)₂SiO_{2/2} (or (R)₂SiO).

In the following description, an oxygen atom O* bonded to other silicon atoms means an oxygen atom through which two silicon atoms are bonded to each other and which is intended as an oxygen atom in a bond expressed as Si—O—Si. Accordingly, there is one O* between silicon atoms of two organosiloxy units.

The M unit means an organosiloxy unit expressed as (R)₃SiO_{1/2}. Here, R represents a hydrogen atom or an organic group. The number (here, 3) following (R) means that three hydrogen atoms or organic groups are bonded to a silicon atom. That is, the M unit contains one silicon atom, three hydrogen atoms or organic groups, and one oxygen atom O*. More specifically, the M unit contains three hydrogen atoms or organic groups bonded to one silicon atom, and an oxygen atom O* bonded to one silicon atom.

The D unit means an organosiloxy unit expressed as (R)₂SiO_{2/2} (R represents a hydrogen atom or an organic group). That is, the D unit contains one silicon atom, two hydrogen atoms or organic groups bonded to the silicon atom, and two oxygen atoms O* bonded to other silicon atoms.

The T unit means an organosiloxy unit expressed as RSiO_{3/2} (R represents a hydrogen atom or an organic group). That is, the T unit contains one silicon atom, one hydrogen atom or organic group bonded to the silicon atom, and three oxygen atoms O* bonded to other silicon atoms.

The Q unit means an organosiloxy unit expressed as SiO₂. That is, the Q unit contains one silicon atom, and four oxygen atoms O* bonded to other silicon atoms.

Examples of organic groups include alkyl groups such as a methyl group, an ethyl group, a propyl group, a butyl group, a pentyl group, a hexyl group, a cyclohexyl group, a heptyl group; aryl groups such as a phenyl group, a tolyl group, a xylyl group, a naphthyl group; aralkyl groups such as a benzyl group, a phenethyl group; and halogen-substituted monovalent hydrocarbon groups such as halogenated alkyl groups (e.g. a chloromethyl group, 3-chloropropyl group, 3,3,3-trifluoropropyl group, etc.). As the organic groups, unsubstituted or halogen-substituted monovalent hydrocarbon groups with 1 to 12 carbon atoms (preferably 1 to 10 carbon atoms) are preferred.

The structure of the silicone resin which forms the silicone resin layer 14 is not particularly limited, but it preferably contains at least one kind of specified organosiloxy unit selected from the group consisting of an organosiloxy unit (M unit) expressed by (R)₃SiO_{1/2} and an organosiloxy unit (T unit) expressed by (R)SiO_{3/2} because of more excellent balance between the laminating property and the peelability of the glass substrate 16.

In addition, the ratio of the aforementioned specified organosiloxy unit to the total organosiloxy units is preferably 60 mol % or more, and more preferably 80 mol % or more. The upper limit of the ratio is not particularly limited, but it is often 100 mol % or less. Here, the ratio between the numbers (molar quantities) of the M units and the T units can be calculated from a value of a peak area ratio based on ²⁹Si—NMR.

The silicone resin is typically obtained by curing (crosslinking and curing) curable silicone which can be formed into the silicone resin by curing treatment. That is, the silicone resin corresponds to a cured product of curable silicone.

Curable silicone is classified into condensation-reactive silicone, addition-reactive silicone, ultraviolet curable silicone, and electron beam curable silicone in accordance with a curing mechanism thereof. Any type of curable silicone may be used. Among them, condensation-reactive silicone, and addition-reactive silicone are preferred.

As the condensation-reactive silicone, a hydrolyzable organosilane compound which is a monomer, a mixture thereof (monomer mixture), or a partially hydrolyzed condensate (organopolysiloxane) obtained by partial hydrolytic condensation reaction of the monomer or the monomer mixture may be suitably used. In addition, a mixture of the partially hydrolyzed condensate and the monomer may be used. Here, one kind of monomer may be used alone, or two or more kinds of monomers may be used together. When hydrolytic condensation reaction (sol-gel reaction) is allowed to proceed by use of the condensation-reactive silicone, the silicone resin can be formed.

The aforementioned monomer (hydrolyzable organosilane compound) is typically represented by (R′—)ₐSi(—Z)₄₋ₙ, where a is an integer from 0 to 3, R′ represents a hydrogen atom or an organic group, and Z represents a hydroxyl group or a hydrolyzable group. In this formula, a compound with a=3 is an M monomer, a compound with a=2 is a D monomer, a compound with a=1 is a T monomer, and a compound with a=0 is a Q monomer. In each monomer, each Z group is typically a hydrolyzable group. In addition, when there are two or three R's (when a is two or three), the R's may be different from one another.

The curable silicone which is a partially hydrolyzed condensate can be obtained by a reaction in which a part of the Z groups of the monomer are converted to oxygen atoms O*. When the Z groups of the monomer are hydrolyzable groups, the Z groups are converted into hydroxyl groups by hydrolytic reaction. Next, through dehydration condensation reaction between two hydroxyl groups bonded to different silicon atoms, the two silicon atoms bond to each other via an oxygen atom O*. Hydroxyl groups (or Z groups which have not been hydrolyzed yet) remain in the curable silicone. When the curable silicone is cured, the remaining hydroxyl groups or Z groups go through the same reaction as described above. Thus, the curable silicone is cured. The cured product of the curable silicone is typically a three-dimensionally crosslinked polymer (silicone resin).

When each Z group of the monomer is a hydrolyzable group, the Z group includes an alkoxy group, a halogen atom (such as a chlorine atom), an acyloxy group, and an isocyanate group. In most cases, a monomer in which Z group is an alkoxy group is used, and such a monomer is also referred to as alkoxysilane.

Each alkoxy group is a hydrolyzable group which is lower in reactivity than any other hydrolyzable group such as a chlorine atom. Unreacted alkoxy groups often remain as Z groups together with hydroxyl groups in the curable silicone obtained by using the monomer (alkoxysilane) in which the Z group is an alkoxy group.

As the aforementioned condensation-reactive silicone, a partially hydrolyzed condensate (organopolysiloxane) obtained by a hydrolyzable organosilane compound is preferred from the viewpoints of control of reaction and handling. The partially hydrolyzed condensate can be obtained by subjecting the hydrolyzable organosilane compound to partially hydrolyzed condensation. A method for the partially hydrolyzed condensation is not particularly limited. Typically, the partially hydrolyzed condensate is produced by reaction of the hydrolyzable organosilane compound in a solvent under the presence of a catalyst. As the catalyst, an acid catalyst and an alkali catalyst can be used. In addition, it is typically preferable that water is used for the hydrolytic reaction. As the partially hydrolyzed condensate, a product produced by reaction of the hydrolyzable organosilane compound in a solvent under the presence of an acid or alkali solution is preferred.

In a preferred mode of the hydrolyzable organosilane compound to be used, alkoxysilane may be used as described above. That is, curable silicone obtained by hydrolytic reaction and condensation reaction of alkoxysilane may be used in one preferred mode of the curable silicone.

When alkoxysilane is used, the degree of polymerization in the partially hydrolyzed condensate tends to increase, and thus, the effect of the invention is more improved.

As the addition-reactive silicone, a curable composition which contains a main agent and a crosslinking agent and which is cured under the presence of a catalyst such as a platinum catalyst can be used preferably. Curing the addition-reactive silicone is promoted by heating treatment. The main agent in the addition-reactive silicone is preferably organopolysiloxane having an alkenyl group (such as a vinyl group) bonded to a silicon atom (that is, organoalkenylpolysiloxane, which is preferably linear), and an alkenyl group serves as a crosslinking point. It is preferred that the crosslinking agent in the addition-reaction silicone is organopolysiloxane having a hydrogen atom bonded to a silicon atom (a hydroxyl group), that is, organohydrogenpolysiloxane (which is preferably linear), and a hydrosilyl group serves as a crosslinking point.

The addition-reactive silicone is cured by addition reaction between the main agent and the crosslinking point of the crosslinking agent. In order to more improve the heat resistance due to the crosslinking structure, it is preferable that the molar ratio of hydrogen atoms bonded to silicon atoms of organohydrogenpolysiloxane relative to alkenyl groups of organoalkenylpolysiloxane is 0.5 to 2.

A weight-average molecular weight (Mw) of the curable silicone such as the condensation-reactive silicone or the addition-reactive silicone is not particularly limited, but it is preferably 5,000 to 60,000, and more preferably 5,000 to 30,000. When the Mw is 5,000 or more, the curable silicone is excellent from the viewpoint of applicability. When the Mw is 60,000 or less, the curable silicone is excellent from the viewpoint of solubility to a solvent and applicability.

The method for producing the aforementioned silicone resin layer 14 is not particularly limited, but a known method can be used. In particular, the following method for producing the silicone resin layer 14 is preferred due to excellent productivity of the silicone resin layer 14. That is, a curable composition containing curable silicone serving as the aforementioned silicone resin and a metal compound containing the specified element is applied onto the support substrate 12. A solvent is removed if necessary. Thus, a coating film is formed, and the curable silicone in the coating film is cured. Thus, the silicone resin layer 14 is formed.

As described above, a hydrolyzable organosilane compound which is a monomer and/or a partially hydrolyzed condensate (organopolysiloxane) obtained by partial hydrolytic condensation reaction of the monomer can be used as the curable silicone. In addition, a mixture of organoalkenylpolysiloxane and organohydrogenpolysiloxane can be also used as the curable silicone.

The metal compound contains a specified element and is contained in the aforementioned curable composition. The structure of the metal compound is not particularly limited, but a known metal compound may be used as long as the predetermined specified element is contained. In the present specification, a so-called complex belongs to the aforementioned metal compound.

As the metal compound containing a specified element, a complex containing the specified element is preferred. The complex is an aggregate in which an atom or ion of a metal element is disposed at the center, and a ligand (an atom, an atomic group, a molecule or an ion) is bonded thereto.

The kind of ligand contained in the aforementioned complex is not particularly limited. For example, the ligand may be selected from the group consisting of β-diketone, carboxylic acid, alkoxide, and alcohol.

Examples of such β-diketones include acetylacetone, methyl acetoacetate, ethyl acetoacetate, benzoylacetone.

Examples of such carboxylic acids include acetic acid, 2-ethylhexanoic acid, naphthenic acid, neodecanoic acid.

Examples of such alkoxides include methoxide, ethoxide, isopropoxide, butoxide.

Examples of such alcohols include methanol, ethanol, n-propanol, isopropanol, n-butanol, t-butanol.

Examples of such metal compounds containing the specified element include an organic manganese compound such as tris (2,4-pentanedionato) manganese(IH), an organic iron compound such as tris (2,4-pentanedionato) iron(III) or tris (2-ethylhexanoate) iron(III), an organic cobalt compound such as bis (2,4-pentanedionato) cobalt(HI), an organic nickel compound such as bis (2,4-pentanedionato) nickel(II), an organic copper compound such as copper(II) neodecanoate, an organic bismuth compound such as bismuth(II) neodecanoate, an organic zirconium compound such as zirconium tetra (monomethylethoxide), zirconium tetra (monoethylethoxide), zirconium tetra (monobutylethoxide), or zirconium n-propylate, an organic cerium compound such as tris (2-ethylhexanoate) cerium(III), and an organic chromium compound such as tris (2,4-petanedionato) chrominum(III).

The content of the metal compound containing the specified element in the curable composition is not particularly limited, but it is preferable to adjust the content of the metal compound so that the content of the specified element in the aforementioned silicone resin layer can be set within the preferred range.

When the condensation-reactive silicone is used as the curable silicone, the curable composition may contain a curing catalyst as a metal compound containing another metal element in order to promote condensation reaction if necessary. Examples of such curing catalysts for promoting condensation reaction include an aluminum chelate compound such as aluminum tris(acetylacetonate) or aluminum tris(ethylacetoacetate), and a tin compound such as dibutyltin dilaurate or bis(2-ethylhexanoate) tin(II).

When the addition-reactive silicone is used as the curable silicone, the curable composition may contain a platinum catalyst as a metal compound containing the other metal element if necessary.

The platinum catalyst is a catalyst for advancing/promoting a hydrosilylation reaction between an alkenyl group in the aforementioned organoalkenylpolysiloxane and a hydrogen atom in the aforementioned organohydrogenpolysiloxane.

A solvent may be contained in the curable composition. In that case, the thickness of the coating film can be controlled by the adjustment of the concentration of the solvent. In particular, in the curable composition containing curable silicone, the content of the curable silicone is preferably 1 to 80 mass % and more preferably 1 to 50 mass % relative to the total mass of the composition in terms of excellent handleability and easy control of the film thickness of the silicone resin layer 14.

The solvent is not particularly limited as long as the solvent can dissolve the curable silicone easily under a working environment and can be removed through volatilization. Examples of such solvents include butyl acetate, 2-heptanone, 1-methoxy-2-propanol acetate, octamethylcyclotetrasiloxane, isoparaffin-based solvents, etc.

In addition, various additives may be contained in the curable composition. For example, a leveling agent may be contained. Examples of such leveling agents include fluorine-based leveling agents such as Megafac F-558, Megafac F-560, and Megafac F-561 (each manufactured by DIC Corporation).

### <Glass Laminate and Manufacturing Method Thereof>

The glass laminate 10 is a laminate including the support substrate 12, the glass substrate 16, and the silicone resin layer 14 disposed between those substrates as described above.

The method for manufacturing the glass laminate 10 is not particularly limited, but a method for forming the silicone resin layer 14 on the surface of the support substrate 12 is preferred in order to obtain a laminate in which the peel strength (x) is higher than the peel strength (y). In particular, the following method is preferred. That is, a curable composition, which contains a curable silicone and a metal compound containing a specified element, is applied onto a surface of the support substrate 12, and curing treatment is performed on the coating film thus obtained, so as to obtain a silicone resin layer 14. Next, the glass substrate 16 is laminated on a surface of the silicone resin layer 14. Thus, the glass laminate 10 is manufactured.

When the curable silicone is cured on the surface of the support substrate 12, the curable silicone adheres to the surface of the support substrate 12 due to interaction therewith during curing reaction. It is considered that the peel strength between the silicone resin and the surface of the support substrate 12 can be thus enhanced. Accordingly, even when the glass substrate 16 and the support substrate 12 are made of one and the same material, it is possible to provide a difference in peel strength between the glass substrate 16 and the support substrate 12 with respect to the silicone resin layer 14.

Hereinafter, a step of forming a layer of curable silicone on a surface of the support substrate 12 to form the silicone resin layer 14 on the surface of the support substrate 12 will be referred to as resin layer forming step 1. A step of laminating the glass substrate 16 on a surface of the silicone resin layer 14 to form the glass laminate 10 will be referred to as lamination step 1. A procedure of each step will be described in detail.

### (Resin Layer Forming Step 1)

In the resin layer forming step 1, a layer of curable silicone is formed on a surface of the support substrate 12 to form the silicone resin layer 14 on the surface of the support substrate 12.

First, in order to form a layer of curable silicone on the support substrate 12, the aforementioned curable composition is applied onto the support substrate 12. Next, preferably, curing treatment is performed on the layer of the curable silicone to form a cured layer.

The method for applying the curable composition onto the surface of the support substrate 12 is not particularly limited, but a known method can be used. Examples of such known methods include a spray coating method, a die coating method, a spin coating method, a dip coating method, a roll coating method, a bar coating method, a screen printing method, a gravure coating method.

Subsequently, the curable silicone on the support substrate 12 is cured to form a cured layer (silicone resin layer).

The curing method is not particularly limited, but treatment optimized in accordance with the kind of the curable silicone to be used is performed. For example, when condensation-reactive silicone and addition-reactive silicone are used, thermal curing treatment is preferred as the curing treatment.

As a temperature condition for the thermal curing, 150 to 550° C. is preferable, and 200 to 450° C. is more preferable. In addition, a heating period is typically preferably 10 to 300 minutes, and more preferably 20 to 120 minutes. Here, the heating conditions may be carried out with the temperature condition changed stepwise.

In the thermal curing treatment, it is preferable that post-curing (main curing) is performed after pre-curing (preliminary curing) is performed. When the pre-curing is performed, it is possible to obtain the silicone resin layer 14 which is excellent in heat resistance.

### (Lamination Step 1)

The lamination step 1 is a step of laminating the glass substrate 16 on a surface of the silicone resin layer 14 obtained in the aforementioned resin layer forming step to obtain the glass laminate 10 provided with the support substrate 12, the silicone resin layer 14 and the glass substrate 16 arranged in this order.

The method for laminating the glass substrate 16 on the silicone resin layer 14 is not particularly limited, and it is possible to use a known method.

Examples of the method include a method of overlaying the glass substrate 16 on the surface of the silicone resin layer 14 under a normal pressure environment. If necessary, after overlaying the glass substrate 16 on the surface of the silicone resin layer 14, the glass substrate 16 may be bonded to the silicone resin layer 14 by pressure bonding using a roll or a press. Bubbles interposed between the silicone resin layer 14 and the glass substrate 16 are relatively easily removed by the pressure bonding using the roll or the press, which is preferable.

Pressure bonding by a vacuum lamination method or a vacuum press method is more preferable because the interposition of bubbles is suppressed and good adhesion can be secured. Pressure bonding under a vacuum also has the advantage that, even in a case where minute bubbles remain, heating does not cause the bubbles to grow and distortion defects of the glass substrate 16 are not easily caused.

When the glass substrate 16 is to be laminated, it is preferable that the surface of the glass substrate 16 which is to be in contact with the silicone resin layer 14 is cleansed sufficiently in order to be laminated in an environment with a high degree of cleanliness. The higher degree of cleanliness is desired in order to secure excellent flatness in the glass substrate 16.

After the glass substrate 16 is laminated, pre-annealing treatment (heating treatment) may be performed if necessary. When the pre-annealing treatment is performed, the adhesion of the laminated glass substrate 16 to the silicone resin layer 14 is improved so that a proper peel strength (y) can be obtained.

So far, detailed description has been made about the case where a glass substrate is used as a substrate, however, the kind of the substrate is not limited.

Examples of such substrates include a metal substrate, a semiconductor substrate, a resin substrate, and a glass substrate. In addition, the substrate may be a substrate formed of a plurality of materials belonging to the same category, such as a metal sheet formed of two kinds of different metals. Further, the substrate may be a composite substrate formed of materials belonging to different categories (for example, two or more kinds of materials selected from metal, semiconductor, resin, and glass), such as a substrate formed of resin and glass.

The thickness of the substrate such as the metal sheet or the semiconductor substrate is not particularly limited. However, in order to make the substrate thinner in thickness and lighter in weight, the thickness is preferably 0.5 mm or less, more preferably 0.4 mm or less, and further more preferably 0.2 mm or less. In addition, the lower limit of the thickness is not particularly limited, but it is preferably 0.005 mm or more.

Further, the area (the area of the main surface) of the substrate is not particularly limited. From the viewpoint of productivity of an electronic device, it is preferable that the area of the substrate is 300 cm² or more.

Furthermore, the shape of the substrate is not particularly limit, and it may be rectangular or circular. In addition, an orientation flat (which is a flat part formed in an outer circumference of the substrate) or notches (one or more V-shaped notches formed at an outer circumferential edge of the substrate) may be formed in the substrate.

### <Resin Substrate and Method for Manufacturing Laminate Using the Resin Substrate>

As the aforementioned resin substrate, it is preferable to use a resin substrate whose heat resistance is high enough to endure a heating treatment in a device manufacturing step. Examples of resins for forming the resin substrate include polybenzimidazole (PBI) resin, polyimide (PI) resin, polyether ether ketone (PEEK) resin, polyamide (PA) resin, fluororesin, epoxy resin, polyphenylene sulfide (PPS) resin. Particularly, a polyimide resin substrate made of polyimide resin is preferred from the viewpoints of excellent heat resistance, excellent chemical resistance, a low thermal expansion coefficient, a high mechanical property, etc.

In addition, it is preferable that the resin substrate has a smooth surface in order to form high-definition wiring or the like for an electronic device on the resin substrate. Specifically, the surface roughness Ra of the resin substrate is preferably 50 nm or less, more preferably 30 nm or less, and further more preferably 10 nm or less. From the viewpoint of handleability in the manufacturing step, the thickness of the resin substrate is preferably 1 μm or more, and more preferably 10 μm or more. In addition, from the viewpoint of flexibility, the thickness is preferably 1 mm or less, and more preferably 0.2 mm or less.

As for the thermal expansion coefficient of the resin substrate, it is preferable that the difference in the thermal expansion coefficient from that of the electronic device or the support substrate is smaller in order to suppress warpage of the laminate after heating or after cooling. Specifically, the difference in thermal expansion coefficient between the resin substrate and the support substrate is preferably 0 to 90×10⁻⁶/° C., and more preferably 0 to 30×10⁻⁶/° C.

When the resin substrate is used as the substrate, the method for manufacturing the laminate is not particularly limited. For example, the laminate can be manufactured in the same manner as when the glass substrate is used. That is, a silicone resin layer is formed on a support substrate, and the resin substrate is laminated on the silicone resin layer. Thus, the laminate can be manufactured.

Hereinafter, the laminate having the support substrate, the silicone resin layer and the resin substrate arranged in this order will be also referred to as resin laminate.

As another method for manufacturing the resin laminate, a method in which a silicone resin layer is formed on a surface of the resin substrate to manufacture the resin laminate is also preferable.

There is generally a tendency that adhesion of the silicone resin layer to the resin substrate is low. Therefore, even when a silicone resin layer is formed on a surface of the resin substrate and the resin substrate with the obtained silicone resin layer is laminated on a support substrate to obtain a resin laminate, there is a tendency that the peel strength (x) between the support substrate and the silicone resin layer exceeds the peel strength (y′) between the silicone resin layer and the resin substrate. Particularly when a glass sheet is used as the support substrate, the tendency is increased.

That is, the resin laminate can be separated into the resin substrate and the silicone resin layer-attached support substrate in the same manner as in the case of the glass laminate.

Another method for manufacturing the aforementioned resin laminate includes a step of forming a layer of curable silicone on a surface of a resin substrate to form a silicone resin layer on the surface of the resin substrate (resin layer forming step 2), and a step of laminating a support substrate on a surface of the silicone resin layer to form a resin laminate (lamination step 2).

A procedure of each of the aforementioned steps will be described below in detail.

### (Resin Layer Forming Step 2)

In the resin layer forming step 2, a layer of curable silicone is formed on a surface of a resin substrate to form a silicone resin layer on the surface of the resin substrate. In this step, a silicone resin layer-attached resin substrate, which has the resin substrate and the silicone resin layer arranged in this order, is obtained.

In this step, in order to form the layer of the curable silicone on the resin substrate, the aforementioned curable composition is applied onto the resin substrate. Next, it is preferable that curing treatment is performed on the layer of the curable silicone to form a cured layer.

The method for applying the curable composition onto the surface of the resin substrate is not particularly limited, and a known method can be used. Examples of such known methods include a spray coating method, a die coating method, a spin coating method, a dip coating method, a roll coating method, a bar coating method, a screen printing method, a gravure coating method.

Subsequently, the curable silicone on the resin substrate is cured to form a cured layer (silicone resin layer).

The curing method is not particularly limited, and treatment optimized in accordance with the kind of the curable silicone to be used is performed. For example, when condensation-reactive silicone and addition-reactive silicone are used, thermal curing treatment is preferred as the curing treatment.

As for conditions of the thermal curing treatment, the thermal curing treatment is performed within the range of the heat resistance of the resin substrate. For example, as a temperature condition for the thermal curing, 50 to 400° C. is preferable, and 100 to 300° C. is more preferable. In addition, a heating period is typically preferably 10 to 300 minutes, and more preferably 20 to 120 minutes.

The mode of the silicone resin layer to be formed has been described above.

(Lamination Step 2) The lamination step 2 is a step of laminating a support substrate on a surface of the silicone resin layer to obtain a resin laminate. That is, this step is a step of forming a resin laminate using the silicone resin layer-attached resin substrate and the support substrate.

The method for laminating the support substrate on the silicone resin layer is not particularly limited, and known methods may be used. Examples of the method include the aforementioned method described in the lamination step 1 in the manufacturing of the glass laminate.

If necessary, after the support substrate is laminated, heating treatment may be performed. When the heating treatment is performed, the adhesion of the laminated support substrate to the silicone resin layer is improved so that a proper peel strength (x) can be obtained.

As a temperature condition for the heating treatment, 50 to 400° C. is preferable, and 100 to 300° C. is more preferable. In addition, a heating period is typically preferably 1 to 120 minutes, and more preferably 5 to 60 minutes. Here, the heating conditions may be carried out with the temperature condition changed stepwise.

In addition, when the resin laminate is heated in a step forming an electronic device member described later, the heating treatment may be skipped.

In order to improve the peel strength (x) to adjust the balance between the peel strength (x) and the peel strength (y′), it is preferable that surface treatment is performed on at least one of the support substrate and the silicone resin layer, and it is more preferable that the surface treatment is performed on the silicone resin layer, before the support substrate is laminated on the silicone resin layer.

Examples of preferable methods for the surface treatment include corona treatment, plasma treatment, and UV ozone treatment. Among them, the corona treatment is preferred.

The silicone resin layer-attached resin substrate can be manufactured in a so-called roll-to-roll system in which a silicone resin layer is formed on a surface of a resin substrate rolled in a roll shape and the silicone resin layer-attached resin substrate thus obtained is then taken up in a roll shape again. This system is excellent in manufacturing efficiency.

In the case where the silicone resin layer is formed on the support substrate, there is a tendency that the thickness of an outer circumferential portion of the silicone resin layer becomes thicker than the thickness of a center portion thereof due to a so-called coffee ring phenomenon when the curable composition is applied onto the support substrate. In such a case, a support substrate part where the outer circumferential portion of the silicone resin layer is disposed must be cut and removed. When the support substrate is a glass sheet, much labor and large cost are required.

On the other hand, when the silicone resin layer is formed on the resin substrate, even though the aforementioned problem arises, it is comparatively easy to remove the resin substrate part where the outer circumferential portion of the silicone resin layer is disposed, since the resin substrate is generally excellent in handleability and advantageous in cost.

### <Semiconductor Substrate and Method for Manufacturing Laminate Using the Semiconductor Substrate>

As a material of the aforementioned semiconductor substrate, Si, SiC, GaN, gallium oxide, diamond, etc. can be used. A substrate of Si is also referred to as Si wafer.

It is preferable that the semiconductor substrate has a smooth surface in order to form high-definition wiring or the like for an electronic device on the semiconductor substrate. Specifically, the surface roughness Ra of the semiconductor substrate is preferably 50 nm or less, more preferably 30 nm or less, and further more preferably 10 nm or less.

From the viewpoint of handleability in the manufacturing step, the thickness of the semiconductor substrate is preferably 1 μm or more, and more preferably 10 μm or more. From the viewpoint of miniaturization of the electronic device, the thickness is preferably 1 mm or less, and more preferably 0.2 mm or less.

As for the thermal expansion coefficient of the semiconductor substrate, it is preferable that the difference in the thermal expansion coefficient from that of the electronic device or the support substrate is smaller in order to suppress warpage of the laminate after heating or after cooling. Specifically, the difference in thermal expansion coefficient between the semiconductor substrate and the support substrate is preferably 0 to 90×10⁻⁶/° C., and more preferably 0 to 30×10⁻⁶/° C.

When the semiconductor substrate is used as the substrate, the method for manufacturing the laminate is not particularly limited. For example, the laminate can be manufactured in the same manner as in the aforementioned case where the glass substrate is used. That is, a silicone resin layer is formed on a support substrate, and the semiconductor substrate is laminated on the silicone resin layer. Thus, the laminate can be manufactured.

Hereinafter, the laminate having the support substrate, the silicone resin layer and the semiconductor substrate arranged in this order will be referred to as semiconductor laminate.

In addition, the end portion degradation is also suppressed in the semiconductor laminate as will be described later.

### (Laminate)

It is possible to use the laminate (for example, the aforementioned glass laminate 10) of the present invention for various purposes and examples thereof include applications for manufacturing electronic parts such as a display device panel to be described below, a PV, a thin film secondary battery, a semiconductor wafer having a circuit formed on the surface thereof, a receiving sensor panel. In these applications, the laminate may sometimes be exposed (for example, for 20 minutes or more) to high temperature conditions (for example, 450° C. or higher) under an air atmosphere.

Here, the display device panel includes an LCD, an OLED, an electronic paper, a plasma display panel, a field emission panel, a quantum dot LED panel, a micro LED display panel, an MEMS (Micro Electro Mechanical Systems) shutter panel.

Here, the receiving sensor panel may include an electromagnetic wave receiving sensor panel, an X-ray receiving sensor panel, an ultraviolet ray receiving sensor panel, a visible ray receiving sensor panel, an infrared ray receiving sensor panel. A substrate for use in such a receiving sensor panel may be reinforced with a reinforcing sheet of resin or the like.

FIG. 1 shows a mode in which one substrate (e.g. a glass substrate, a resin substrate or a semiconductor substrate) is laminated on a support substrate through a silicone resin layer. However, the laminate according to the present invention is not limited to this mode. For example, the laminate may be obtained in a mode (hereinafter also referred to as “multi-lamination mode”) in which a plurality of substrates are laminated on a support substrate through a silicone resin layer.

The multi-lamination mode is a mode in which each of a plurality of substrates is in contact with a support substrate through a silicone resin layer. That is, the mode is not a mode in which a plurality of substrates are overlapped (only one of the substrates is in contact with the support substrate through a silicone resin layer).

In the multi-lamination mode, for example, a plurality of silicone resin layers are provided for a plurality of substrates respectively, and the substrates and the silicone resin layers are disposed on a single support substrate. However, the invention is not limited to this mode. For example, a plurality of substrates may be individually disposed on a single silicone resin layer (which is, for example, as large as a support substrate) formed on a single support substrate.

### <Electronic Device and Manufacturing Method Thereof>

In the present invention, an electronic device including a substrate and an electronic device member (hereinafter referred to as “member-attached substrate”) is manufactured using the aforementioned laminate.

Detailed description will be made below about a method for manufacturing an electronic device using the aforementioned glass laminate 10.

The method for manufacturing the electronic device is not particularly limited, but from the viewpoint of excellent productivity of the electronic device, preferred is a method in which an electronic device member is formed on a glass substrate in the glass laminate to manufacture an electronic device member-attached laminate, and the electronic device member-attached laminate thus obtained is separated into an electronic device (member-attached substrate) and a silicone resin layer-attached support substrate with the glass substrate side interface of the silicone resin layer as a peeling surface.

The step of forming an electronic device member on the glass substrate in the glass laminate to manufacture an electronic device member-attached laminate will be referred to as a member forming step, and a step of separating the electronic device member-attached laminate into a member-attached substrate and a silicone resin layer-attached support substrate with the glass substrate side interface of the silicone resin layer as the peeling surface will be referred to as a separation step.

Detailed description will be made below about materials and procedures used in each step.

### (Member Forming Step)

The member forming step is a step of forming an electronic device member on the glass substrate 16 in the glass laminate 10. More specifically, as illustrated in FIG. 2A, an electronic device member 20 is formed on the second main surface 16b (exposed surface) of the glass substrate 16 to obtain an electronic device member-attached laminate 22.

First, detailed description will be made about the electronic device member 20 used in this step, and then detailed description will be made about the procedures of subsequent steps.

### (Electronic Device Member (Functional Element))

The electronic device member 20 is a member formed on the glass substrate 16 in the glass laminate 10 and constitutes at least a part of the electronic device. More specifically, examples of the electronic device member 20 include members used for an electronic component such as a display device panel, a photovoltaic cell, a thin film secondary battery, or a semiconductor wafer having a circuit formed on the surface thereof, a member used for a receiving sensor panel (for example, a member for a display device, a member for a photovoltaic cell, a member for a thin film secondary battery, a circuit for an electronic component, or a member for a receiving sensor).

Examples of members for a photovoltaic cell include, as a silicon-type one, a transparent electrode such as a tin oxide of a positive electrode, a silicon layer represented by a p-layer/i-layer/n-layer, a metal of a negative electrode, and the like, as well as various members corresponding to a compound-type, a dye sensitization-type, a quantum dot-type, and the like.

In addition, examples of members for a thin film secondary battery include, as a lithium ion-type one, a transparent electrode such as a metal or a metal oxide of a positive electrode or a negative electrode, a lithium compound of an electrolyte layer, a metal of a current collecting layer, a resin as a sealing layer, and the like, as well as various members corresponding to a nickel hydrogen-type, a polymer-type, a ceramic electrolyte-type, and the like.

In addition, examples of circuits for electronic components include, as CCDs or CMOSs, metals for a conductive portion, silicon oxide or silicon nitride for an insulating portion, and the like, as well as various sensors such as a pressure sensor and an acceleration sensor or various members corresponding to a rigid printed circuit board, a flexible printed circuit board, a rigid flexible printed circuit board, and the like.

### (Step Procedure)

The method for manufacturing the aforementioned electronic device member-attached laminate 22 is not particularly limited. The electronic device member 20 may be formed on the second main surface 16b of the glass substrate 16 of the glass laminate 10 by a known method in accordance with the type of constituents of the electronic device member 20.

Here, the electronic device member 20 does not have to include all of the members (referred to below as the “all members”) ultimately formed on the second main surface 16b of the glass substrate 16, but may be a part of all the members (referred to below as “part of the members”). A substrate with a part of the members attached thereto, which has been peeled from the silicone resin layer 14, may be processed to a substrate with all the members attached thereto (corresponding to an electronic device to be described below) in subsequent steps.

In addition, a member for another electronic device may be formed on the peeling surface (the first main surface 16a) of the substrate with all the members attached thereto, which has been peeled from the silicone resin layer 14. Furthermore, two laminates with all members attached thereto may be used and assembled, and two support substrates each having a silicone resin layer may be then peeled off from the laminates with all members attached thereto. Thus, it is also possible to manufacture a substrate with a member having two glass substrates.

For example, in an example in which an OLED is manufactured, various layer formation and treatments are performed in order to form an organic EL structure on the surface on the opposite side to the silicone resin layer 14 side of the glass substrate 16 (corresponding to the second main surface 16b of the glass substrate 16) of the glass laminate 10. That is, a transparent electrode is formed; a hole injecting layer, a hole transporting layer, a light emitting layer, an electron transporting layer and the like are deposited by vapor deposition on the surface where the transparent electrode has been formed; a back electrode is formed; and sealing is attained by using a sealing plate. Specific examples of the layer formation and treatments include film formation treatments, vapor deposition treatments, sealing plate adhesion treatments.

In addition, for example, in the case where a TFT-LCD is manufactured, there are various types of steps such as a thin film transistor (TFT) forming step of forming a pattern on a metal film, a metal oxide film or the like formed by a general film forming method such as a CVD method or a sputtering method, by using a resist solution on the second main surface 16b of the glass substrate 16 of the glass laminate 10 to form a thin film transistor (TFT), a color filter (CF) forming step of forming a pattern on the second main surface 16b of the glass substrate 16 of another glass laminate 10 by using a resist solution to form a color filter (CF), and a bonding step of laminating the laminate with the TFT obtained in the TFT forming step and the laminate with the CF obtained in the CF forming step.

For example, in the case where a micro LCD display is manufactured, provided are steps such as a thin film transistor (TFT) forming step of forming a pattern on a metal film, a metal oxide film or the like formed by a general film forming method such as a CVD method or a sputtering method, by using a resist solution at least on the second main surface 16b of the glass substrate 16 of the glass laminate 10 to form a thin film transistor (TFT), and an LED mounting step of mounting LED chips on the formed TFT. In addition, a flattening step, a wiring forming step, a sealing step, and the like may be performed.

In the TFT forming step or the CF forming step, the TFT or the CF is formed on the second main surface 16b of the glass substrate 16 by using known photolithography techniques, etching techniques, or the like. In this process, a resist solution is used as a coating solution for forming a pattern.

Here, the second main surface 16b of the glass substrate 16 may be cleaned before forming the TFTs or CFs thereon, as necessary. As a cleaning method, a known dry cleaning or wet cleaning may be used.

In the bonding step, the thin film transistor forming surface of the laminate with the TFT and the color filter forming surface of the laminate with the CF are made to face each other and bonded to each other by using a sealing agent (for example, an ultraviolet curable sealing agent for forming a cell). Thereafter, a liquid crystal material is injected into the cell formed by the laminate with the TFT and the laminate with the CF. Examples of a method for injecting the liquid crystal material include a reduced pressure injection method and a dropping injection method.

When the electronic device member 20 is manufactured, conditions of heating at 450° C. or more under an air atmosphere may be included. According to the laminate of the present invention, the end portion degradation in the silicone resin layer is suppressed even under such conditions.

### (Separation Step)

As illustrated in FIG. 2B, the separation step is a step in which the electronic device member-attached laminate 22 obtained in the aforementioned member forming step is separated into the glass substrate 16 (member-attached substrate) laminated with the electronic device member 20 and the silicone resin layer-attached support substrate 18 with the interface between the silicone resin layer 14 and the glass substrate 16 as a peeling surface to obtain a member-attached substrate (electronic device) 24 including the electronic device member 20 and the glass substrate 16.

In a case where the electronic device member 20 on the glass substrate 16 at the time of peeling is only a part for forming all of the necessary constituent members, the remaining constituent members may be formed on the glass substrate 16 after the separation.

The method for peeling off the glass substrate 16 and the silicone resin layer 14 is not particularly limited. Specifically, for example, it is possible to carry out the peeling by inserting a sharp blade like object into the interface between the glass substrate 16 and the silicone resin layer 14 to give a trigger of peeling, and blowing a mixed fluid of water and compressed air thereon. Preferably, the electronic device member-attached laminate 22 is set on a platen so that the support substrate 12 is on the upper side and the electronic device member 20 side is on the lower side, and the electronic device member 20 side is vacuum adsorbed on the platen. In this state, a blade is first inserted into the interface between the glass substrate 16 and the silicone resin layer 14. Thereafter, the support substrate 12 side is adsorbed by a plurality of vacuum adsorption pads, and the vacuum adsorption pads are raised sequentially in order from the vicinity of the place where the blade is inserted. Accordingly, an air layer is formed at the interface between the silicone resin layer 14 and the glass substrate 16 or a cohesive broken surface of the silicone resin layer 14, and the air layer spreads over the entire interface or the cohesive broken surface. Thus, it is possible to easily peel off the silicone resin layer-attached support substrate 18.

In addition, the silicone resin layer-attached support substrate 18 may be laminated with a new glass substrate to manufacture the glass laminate 10 of the present invention.

When the member-attached substrate 24 is peeled off from the electronic device member-attached laminate 22, it is possible to further suppress electrostatic attraction of fragments of the silicone resin layer 14 to the member-attached substrate 24 by spraying with an ionizer and controlling the humidity.

The method for manufacturing the aforementioned member-attached substrate 24 is suitable for manufacturing a compact display device used for a mobile terminal such as a mobile phone or a PDA. The display device is mainly an LCD or OLED, including, as the LCD, TN-type, STN-type, FE-type, TFT-type, MIM-type, IPS-type, VA-type. Basically, the method can be applied to display devices which are either passive drive-type or active drive-type.

Examples of the member-attached substrate 24 manufactured by the aforementioned method include a panel for a display device having a glass substrate and a member for the display device, a photovoltaic cell having a glass substrate and a member for the photovoltaic cell, a thin film secondary battery having a glass substrate and a member for the thin film secondary battery, a receiving sensor panel having a glass substrate and a member for a receiving sensor, an electronic component having a glass substrate and a member for an electronic device. Examples of panels for a display device include liquid crystal panels, organic EL panels, plasma display panels, field emission panels. Examples of receiving sensor panels include an electromagnetic wave receiving sensor panel, an X-ray receiving sensor panel, an ultraviolet ray receiving sensor panel, a visible ray receiving sensor panel, an infrared ray receiving sensor panel.

The method for manufacturing an electronic device using the glass laminate 10 has been described above in detail. However, it is also possible to manufacture the electronic device even by using the aforementioned resin laminate according to the same procedure as above.

More specifically, another mode of the method for manufacturing the electronic device may include a step of forming a resin laminate using a silicone resin layer-attached resin substrate and a support substrate, a member forming step of forming an electronic device member on a surface of the resin substrate of the resin laminate to obtain an electronic device member-attached laminate, and a separation step of removing the support substrate and the silicone resin layer from the electronic device member-attached laminate to obtain an electronic device including the resin substrate and the electronic device member.

The step of forming the resin laminate may include the aforementioned step including the resin layer forming step 2 and the lamination step 2.

The member forming step and the separation step when the resin laminate is used, may be performed in the same procedure as the member forming step and the separation step when the glass laminate is used.

As described above, due to comparatively weak adhesion between the resin substrate and the silicone resin layer, separation occurs more easily between the resin substrate and the silicone resin layer than between the silicone resin layer and the support substrate in the separation step. This tendency is clear particularly when a glass sheet is used as the support substrate.

In addition, in the aforementioned method for manufacturing an electronic device using the glass laminate 10, the electronic device can be manufactured in the same procedure even by using a semiconductor laminate formed using a semiconductor substrate in place of the glass substrate.

### EXAMPLES

The present invention will be described below specifically along its examples and the like. However, the invention is not limited to those examples. Examples 1 to 18 are working examples, and Examples 19 and 20 are comparative examples. Further, Example 21 is a working example; Example 22, a comparative example; Examples 23 to 25, working examples; Examples 26 to 28, comparative examples; Example 29, a working example; and Example 30, a comparative example.

In each of the following working examples and comparative examples, a glass sheet (240 mm in length, 240 mm in width and 0.5 mm in thickness, and 38×10⁻⁷/° C. in linear expansion coefficient) made of alkali-free borosilicate glass was used as the support substrate, and a glass sheet (240 mm in length, 240 mm in width and 0.2 mm in thickness, and 38×10⁻⁷/° C. in linear expansion coefficient) made of alkali-free borosilicate glass was used as the glass substrate.

### [Synthesis of Curable Silicone 1]

Triethoxymethylsilane (179 g), toluene (300 g), and acetic acid (5 g) were put into a IL flask, and a mixture thereof was stirred at 25° C. for 20 minutes, and further heated to 60° C. to be reacted for 12 hours. Resulting crude reaction solution was cooled down to 25° C., and the crude reaction solution was washed three times with water (300 g).

Chlorotrimethylsilane (70 g) was added to the washed crude reaction solution, and the mixture thereof was stirred at 25° C. for 20 minutes, and further heated to 50° C. to be reacted for 12 hours. Resulting crude reaction solution was cooled down to 25° C., and the crude reaction solution was washed three times with water (300 g).

Toluene was evaporated from the washed crude reaction solution under reduced pressure, and formed into slurry. The slurry was then dried overnight by a vacuum drier to obtain a curable silicone 1 which is a white organopolysiloxane compound. In the curable silicone 1, the ratio of the number of T units to the number of M units was 87:13 (molar ratio).

### Example 1

The curable silicone 1 was dissolved in an isoparaffin-based solvent (Isoper G (manufactured by TonenGeneral Sekiyu K.K). A metal compound and an additive were added to the obtained solution to attain adding quantities in Table 1, and stirred for 5 minutes by use of a mix rotor. Here, the concentration of the curable silicone 1 in the resulting composition X was 50 mass %.

Next, the composition X was applied onto a support substrate so that the thickness of a silicone resin layer after curing can achieve 4 μm. After that, heating treatment was performed at 100° C. for 10 minutes to form a coating film.

Next, heating treatment at 250° C. for 30 minutes was performed on the support substrate where the coating film had been formed. Thus, a silicone resin layer was formed.

After that, a glass substrate was laminated on the silicone resin layer surface of the support substrate under a room temperature by a roll laminator. Thus, a glass laminate was obtained.

In the resulting glass laminate, the support substrate and the glass substrate adhered to the silicone resin layer without generating bubbles, and no distortion defect was observed. In addition, in the glass laminate, the peel strength in the interface between the silicone resin layer and the layer of the support substrate was larger than the peel strength in the interface between the layer of the glass substrate and the silicone resin layer.

### Examples 2 to 17

A glass laminate was obtained in the same procedure as in Example 1, except that the kinds and use quantities of the metal compound and the additive to be used were changed as shown in Table 1 to Table 3.

“Orgatics ZA-45” (manufactured by Matsumoto Fine Chemical Co., Ltd., with a metal content of 21.1%) was used as zirconium tetra-n-propoxide.

In addition, “NEOSTANN U-28” (manufactured by Nitto Kasei Co., Ltd., with a metal content of 29%) was used as bis (2-ethylhexanoate) tin (H).

In addition, “bismuth neodecanoate 16%” (manufactured by Nihon Kagaku Sangyo Co., Ltd., with a metal content of 16%) was used as bismuth (III) neodecanoate.

### Example 18

### [Synthesis of Curable Silicone 2]

### (Synthesis of Organohydrogensiloxane)

A mixture of 1,1,3,3-tetramethyldisiloxane (5.4 g), tetramethylcyclotetrasiloxane (96.2 g), and octamethylcyclotetrasiloxane (118.6 g) was cooled down to 5° C., and while the liquid mixture was stirred, 11.0 g of concentrated sulfuric acid was gradually added to the liquid mixture. After that, 3.3 g of water was further dropped down to the liquid mixture for 1 hour. The liquid mixture was stirred for 8 hours while the temperature of the liquid mixture was kept at 10 to 20° C. Thereafter, toluene was added to the liquid mixture. Washing with water and waste acid separation were performed until a siloxane layer becomes neutral. The neutral siloxane layer was heated and condensed under reduced pressure to remove low-melting temperature fractions of toluene or the like. Thus, organohydrogensiloxane with k=40 and l=40 in the following formula (1) was obtained.

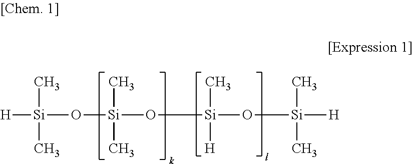

### (Synthesis of Alkenyl Group-Containing Siloxane)

Siliconate of potassium hydroxide with a quantity of Si/K=20000/1 (molar ratio) was added to 1,3-divinyl-1,1,3,3-tetramethyldisiloxane (3.7 g), 1,3,5,7-tetramethyl-1,3,5,7-tetravinylcyclotetrasiloxane (41.4 g), and octamethylcyclotetrasiloxane (355.9 g), and allowed to effect equilibration reaction at 150° C. for 6 hours under a nitrogen atmosphere. After that, ethylene chlorohydrin was added by a quantity of 2 mol relative to K (potassium), and the liquid mixture was neutralized at 120° C. for 2 hours. After that, the resulting liquid mixture was subjected to heating bubbling treatment at 160° C. for 6 hours under 666 Pa to cut out volatile components. Thus, alkenyl group-containing siloxane of La=0.9 in alkenyl equivalent per 100 g and Mw: 26,000 was obtained.

Organohydrogensiloxane and alkenyl group-containing siloxane were mixed so that the molar ratio between all alkenyl groups and hydrogen atoms bonded to all silicon atoms (hydrogen atom/alkenyl group) reached 0.9. Thus, a curable silicone 2 was prepared. 1 part by mass of a silicon compound containing acetylene-based unsaturated groups as expressed by the following formula (2) was mixed into 100 parts by mass of the curable silicone. A platinum catalyst was added to satisfy the content in Table 3. Thus, a mixture A was obtained.

HC≡C—C(CH₃)₂—O—Si(CH₃)₃ (2)

The mixture A was dissolved in octamethyltetracyclosiloxane (XIAMETER PMX-0244, manufactured by Dow Corning Corp.), and metal compounds were added to the resulting solution to attain the added quantities in Table 3, and stirred for 5 minutes by a mix rotor. Here, the concentration of the curable silicone 2 in the resulting composition Y was 30 mass %.

Next, the composition Y was applied onto a support substrate so that the thickness of a silicone resin layer after curing can reach 8 μm. After that, heating treatment was performed at 140° C. for 10 minutes to form a coating film. Next, heating treatment at 220° C. for 30 minutes was performed on the support substrate where the coating film had been formed. Thus, a silicone resin layer was formed.

After that, a glass substrate was laminated on the silicone resin layer surface of the support substrate under a room temperature by a roll laminator. Thus, a glass laminate was obtained.

In the resulting glass laminate, the support substrate and the glass substrate adhered to the silicone resin layer without generating bubbles, and no distortion defect was observed. In addition, in the glass laminate, the peel strength in the interface between the silicone resin layer and the layer of the support substrate was larger than the peel strength in the interface between the layer of the glass substrate and the silicone resin layer.

### Examples 18x to 18z

A glass laminate was obtained in the same procedure as in Example 18, except that the kinds of metal compounds to be used were changed as shown in Table 4.

### Example 19

A glass laminate was obtained in the same procedure as in Example 1, except that no metal compound was used. The silicone resin layer of the glass laminate in Example 19 contained no specified element.

### Example 20

A glass laminate was obtained in the same procedure as in Example 18, except that no predetermined metal compound was used, the temperature of 140° C. was changed to 100° C., and the temperature of 220° C. was changed to 250° C. The silicone resin layer of the glass laminate in Example 20 contained no specified element.

### [Evaluation of End Portion Degradation]

The glass laminate obtained in each example was cut out to obtain a sample measuring 50 mm by 50 mm. Each sample thus obtained was put into an electric furnace preheated to 450° C. Heating treatment for one hour was performed, and the sample was then taken out. The atmosphere in the electric furnace was an air atmosphere.

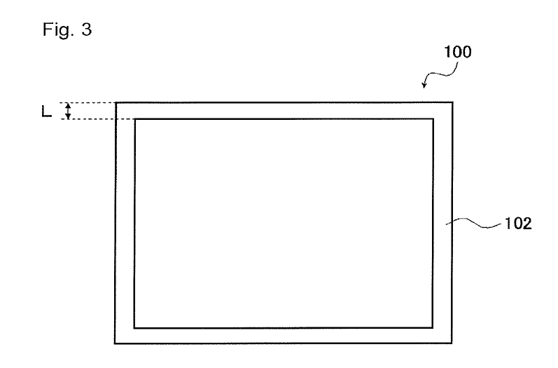

An end portion of the taken-out sample was observed by a microscope to observe a maximum length of a whitened part from the edge of the end portion. The maximum length means a maximum value of length L of the whitened end portion as shown in FIG. 3. The shorter the length L expressing the end portion degradation is, the more excellent the effect is.

The results are shown collectively in Table 1 to Table 4.

TABLE 1

| | | | Example 1 | Example 2 | Example 3 |
|---|---|---|---|---|---|
| composition | kind of curable silicone | | curable silicone 1 | curable silicone 1 | curable silicone 1 |
| | metal | kind | tris(2,4- | tris(2,4- | bis(2,4- |
| | compound 1 | | pentanedionato)manganese | pentanedionato)iron | pentanedionato)cobalt |
| | | | (III) | (III) | (II) |
| | | kind of | Mn | Fe | Co |
| | | metal | | | |
| | | mass (parts | 0.047 | 0.050 | 0.068 |
| | | by mass) of | | | |
| | | metal | | | |
| | | element in | | | |
| | | 100 parts | | | |
| | | by mass of | | | |
| | | silicone | | | |
| | | resin layer | | | |
| | metal | kind | | | |
| | compound 2 | | | | |
| | | kind of | | | |
| | | metal | | | |
| | | mass (parts | | | |
| | | by mass) of | | | |
| | | metal | | | |
| | | element in | | | |
| | | 100 parts | | | |
| | | by mass of | | | |
| | | silicone | | | |
| | | resin layer | | | |
| | additive | kind | tris (2,4- | tris (2,4- | tris (2,4- |
| | | | pentanedionato)aluminum | pentanedionato)aluminum | pentanedionato)aluminum |
| | | | (III) | (III) | (III) |
| | | mass (parts | 0.04 | 0.04 | 0.04 |
| | | by mass) of | | | |
| | | additive in | | | |
| | | 100 parts | | | |
| | | by mass of | | | |
| | | silicone | | | |
| | | resin layer | | | |

| | | | | |
|---|---|---|---|---|
| evaluation result | length of | 0 mm | 0 mm | 0.5 mm |
| | end portion | | | |
| | degradation | | | |

| | | Example 4 | Example 5 | Example 6 |
|---|---|---|---|---|
| composition | kind of curable silicone | curable silicone 1 | curable silicone 1 | curable silicone 1 |

| | | | | |
|---|---|---|---|---|
| metal | kind | bis(2,4- | tris(2,4- | tris(2,4- |
| compound 1 | | pentanedionato)nickel | pentanedionato)chromium | pentanedionato)iron |
| | | (II) | (III) | (III) |
| | kind of | Ni | Cr | Fe |
| | metal | | | |
| | mass (parts | 0.068 | 0.046 | 0.047 |
| | by mass) of | | | |
| | metal | | | |
| | element in | | | |
| | 100 parts | | | |
| | by mass of | | | |
| | silicone | | | |
| | resin layer | | | |
| metal | kind | | zirconium tetra- | zirconium tetra- |
| compound 2 | | | n-propoxide | n-propoxide |
| | kind of | | Zr | Zr |
| | metal | | | |
| | mass (parts | | 0.129 | 0.075 |
| | by mass) of | | | |
| | metal | | | |
| | element in | | | |
| | 100 parts | | | |
| | by mass of | | | |
| | silicone | | | |
| | resin layer | | | |
| additive | kind | tris (2,4- | bis (2- | bis (2- |
| | | pentanedionato)aluminum | ethylhexanoate)tin | ethylhexanoate)tin |
| | | (III) | (II) | (II) |
| | mass (parts | 0.04 | 0.17 | 0.17 |
| | by mass) of | | | |
| | additive in | | | |
| | 100 parts | | | |
| | by mass of | | | |
| | silicone | | | |
| | resin layer | | | |

| | | | | |
|---|---|---|---|---|
| evaluation result | length of | 1.5 mm | 0.5 mm | 0.0 mm |
| | end portion | | | |
| | degradation | | | |

TABLE 2

| | | | Example 7 | Example 8 | Example 9 | Example 10 | Example 11 | Example 12 |
|---|---|---|---|---|---|---|---|---|
| composition | kind of curable silicone | | curable | curable | curable | curable | curable | curable |
| | | | silicone 1 | silicone 1 | silicone 1 | silicone 1 | silicone 1 | silicone 1 |
| | metal | kind | tris (2- | tris (2- | bis (2- | bis (2,4- | bis (2- | copper (II) |
| | compound 1 | | ethylhexanoate) | ethylhexanoate) | ethylhexanoate) | pentanedionato) | ethylhexanoate) | neodecanoate |
| | | | iron (III) | iron (III) | manganese (II) | nickel (II) | (nickel II) | |
| | | kind of | Fe | Fe | Mn | Ni | Ni | Cu |
| | | metal | | | | | | |
| | | mass | 0.001 | 0.064 | 0.047 | 0.051 | 0.040 | 0.040 |
| | | (parts by | | | | | | |
| | | mass) of | | | | | | |
| | | metal | | | | | | |
| | | element in | | | | | | |
| | | 100 parts | | | | | | |
| | | by mass of | | | | | | |
| | | silicone | | | | | | |
| | | resin layer | | | | | | |
| | metal | kind | zirconium | zirconium | zirconium | zirconium | zirconium | zirconium |
| | compound 2 | | tetra-n- | tetra-n- | tetra-n- | tetra-n- | tetra-n- | tetra-n- |
| | | | propoxide | propoxide | propoxide | propoxide | propoxide | propoxide |
| | | kind of | Zr | Zr | Zr | Zr | Zr | Zr |
| | | metal | | | | | | |
| | | mass | 0.090 | 0.075 | 0.090 | 0.090 | 0.090 | 0.075 |
| | | (parts by | | | | | | |
| | | mass) of | | | | | | |
| | | metal | | | | | | |
| | | element in | | | | | | |
| | | 100 parts | | | | | | |
| | | by mass of | | | | | | |
| | | silicone | | | | | | |
| | | resin layer | | | | | | |
| | additive | kind | bis (2- | bis (2- | bis (2- | bis (2- | bis (2- | bis (2- |
| | | | ethylhexanoate) | ethylhexanoate) | ethylhexanoate) | ethylhexanoate) | ethylhexanoate) | ethylhexanoate) |
| | | | tin (II) | tin (II) | tin (II) | tin (II) | tin (II) | tin (II) |
| | | mass | 0.17 | 0.17 | 0.17 | 0.17 | 0.17 | 0.17 |
| | | (parts by | | | | | | |
| | | mass) of | | | | | | |
| | | additive in | | | | | | |
| | | 100 parts | | | | | | |
| | | by mass of | | | | | | |
| | | silicone | | | | | | |
| | | resin layer | | | | | | |

| | | | | | | | |
|---|---|---|---|---|---|---|---|
| evaluation result | ength of | 0.2 mm | 0.0 mm | 0.0 mm | 1.2 mm | 0.9 mm | 0.0 mm |
| | end | | | | | | |
| | portion | | | | | | |
| | degradation | | | | | | |

TABLE 3

| | | | Example 13 | Example 14 | Example 15 | Example 16 | Example 17 | Example 18 |
|---|---|---|---|---|---|---|---|---|
| composition | kind of curable silicone | | curable silicone 1 | curable silicone 1 | curable | curable | curable | curable |
| | | | | | silicone 1 | silicone 1 | silicone 1 | silicone 2 |
| | metal | kind | Bismuth (III) | tris (2- | tris (2- | tris (2- | tris (2- | tris (2- |
| | compound 1 | | neodecanoate | ethylhexanoate) | ethylhexanoate) | ethylhexanoate) | ethylhexanoate) | ethylhexanoate) |
| | | | | cerium (III) | iron (III) | iron (III) | iron (III) | iron (III) |
| | | kind of | Bi | Ce | Fe | Fe | Fe | Fe |
| | | metal | | | | | | |
| | | mass (parts | 0.240 | 0.197 | 0.064 | 0.064 | 0.064 | 0.098 |
| | | by mass) of | | | | | | |
| | | metal | | | | | | |
| | | element in | | | | | | |
| | | 100 parts | | | | | | |
| | | by mass of | | | | | | |
| | | silicone | | | | | | |
| | | resin layer | | | | | | |
| | metal | kind | zirconium | zirconium | zirconium | zirconium | zirconium | zirconium |
| | compound 2 | | tetra- | tetra- | tetra- | tetra- | tetra- | tetra- |
| | | | n-propoxide | n-propoxide | n-propoxide | n-propoxide | n-propoxide | n-propoxide |
| | | kind of | Zr | Zr | Zr | Zr | Zr | Zr |
| | | metal | | | | | | |
| | | mass (parts | 0.090 | 0.075 | 0.075 | 0.075 | 0.075 | 0.392 |
| | | by mass) of | | | | | | |
| | | metal | | | | | | |
| | | element in | | | | | | |
| | | 100 parts | | | | | | |
| | | by mass of | | | | | | |
| | | silicone | | | | | | |
| | | resin layer | | | | | | |
| | additive | kind | bis (2- | bis (2- | bis (2- | bis (2- | | platinum catalyst |
| | | | ethylhexanoate) | ethylhexanoate) | ethylhexanoate) | ethylhexanoate) | | |
| | | | tin (II) | tin (II) | tin (II) | tin (II) | | |
| | | mass (parts | 0.17 | 0.17 | 0.09 | 0.26 | | 0.01 |
| | | by mass) of | | | | | | |
| | | additive in | | | | | | |
| | | 100 parts | | | | | | |
| | | by mass of | | | | | | |
| | | silicone | | | | | | |
| | | resin layer | | | | | | |

| | | | | | | | |
|---|---|---|---|---|---|---|---|
| evaluation result | length of | 0.0 mm | 0.0 mm | 0.0 mm | 0.0 mm | 0.0 mm | 0.0 mm |
| | end portion | | | | | | |
| | degradation | | | | | | |

TABLE 4

| | | | Example 19 | Example 20 | Example 18x | Example 18y | Example 18z |
|---|---|---|---|---|---|---|---|
| composition | kind of curable silicone | | curable silicone 1 | curable silicone 2 | curable silicone 2 | curable silicone 2 | curable silicone 2 |
| | metal | kind | | | tris (2- | tris (2- | tris (2- |
| | compound 1 | | | | ethylhexanoate)- | ethylhexanoate)- | ethylhexanoate)- |
| | | | | | bismuth (III) | bismuth (III) | cerium (III) |
| | | kind of | | | Bi | Bi | Ce |
| | | metal | | | | | |
| | | mass | | | 0.098 | 0.098 | 0.098 |
| | | (parts by | | | | | |
| | | mass) of | | | | | |
| | | metal | | | | | |
| | | element in | | | | | |
| | | 100 parts | | | | | |
| | | by mass | | | | | |
| | | of silicone | | | | | |
| | | resin layer | | | | | |
| | metal | kind | | | zirconium tetra-n- | zirconium stearate | zirconium tetra-n- |
| | compound 2 | | | | propoxide | | propoxide |
| | | kind of | | | Zr | Zr | Zr |
| | | metal | | | | | |
| | | mass | | | 0.392 | 0.392 | 0.392 |
| | | (parts by | | | | | |
| | | mass) of | | | | | |
| | | metal | | | | | |
| | | element in | | | | | |
| | | 100 parts | | | | | |
| | | by mass | | | | | |
| | | of silicone | | | | | |
| | | resin layer | | | | | |
| | additive | kind | tris (2,4- | platinum catalyst | platinum catalyst | platinum catalyst | platinum catalyst |
| | | | pentanedionato)- | | | | |
| | | | aluminum (III) | | | | |
| | | mass (parts | 0.04 | 0.01 | 0.01 | 0.01 | 0.01 |
| | | by mass) of | | | | | |
| | | additive in | | | | | |
| | | 100 parts | | | | | |
| | | by mass of | | | | | |
| | | silicone | | | | | |
| | | resin layer | | | | | |

| | | | | | | |
|---|---|---|---|---|---|---|
| evaluation result | length of | 3.0 mm | 3.0 mm | 0.0 mm | 0.0 mm | 0.0 mm |
| | end portion | | | | | |
| | degradation | | | | | |

As shown in Table 1 to Table 4, it was confirmed that each laminate according to the present invention showed a desired effect.

Among them, it was confirmed that the effect was more excellent when the silicone resin layer contained iron, manganese, copper, cerium, or bismuth as a specified element.

On the other hand, the effect was inferior in Examples 19 and 20 where the silicone resin layer did not contain any specified element.

After the aforementioned evaluation of the end portion degradation was made, a stainless steel blade 0.1 mm thick was inserted into the interface between the glass substrate and the silicone resin layer in each of the glass laminates in Examples 1 to 16 so as to form a trigger portion for peeling. After that, the glass substrate was fully fixed, and the support substrate was raised. As a result, it was confirmed that the glass substrate could be peeled easily.

On the other hand, in Example 17 where bis(2-ethylhexanoate) tin(II) was not added but zirconium tetra-n-propoxide was added, in some cases, the support substrate was cracked due to high peel strength when the glass substrate was fully fixed and the support substrate was raised after a trigger portion was formed.

### Examples 21 and 22

Using each of the glass laminates in Examples 18 and 20, the aforementioned evaluation of end portion degradation was made in the same procedure, except that the temperature in the [evaluation of end portion degradation] was changed from 450° C. to 400° C.

The silicone resin layer of the glass laminate in Example 22 did not contain any specified element. The results are shown in Table 5.

The evaluation condition in Table 5 shows the temperature and time with which evaluation was made in the evaluation of the end portion degradation.

TABLE 5

| | | | Example 21 | Example 22 |
|---|---|---|---|---|
| composition | kind of curable silicone | | curable silicone 2 | curable silicone 2 |
| | metal | kind | tris (2- | |
| | compound 1 | | ethylhexanoate) | |
| | | | iron (III) | |
| | | kind of metal | Fe | |
| | | mass (parts by mass) | 0.098 | |
| | | of metal element in | | |
| | | 100 parts by mass of | | |
| | | silicone resin layer | | |
| | metal | kind | zirconium tetra-n- | |
| | compound 2 | | propoxide | |
| | | kind of metal | Zr | |
| | | mass (parts by mass) | 0.392 | |
| | | of metal element in | | |
| | | 100 parts by mass of | | |
| | | silicone resin layer | | |
| | additive | kind | platinum catalyst | platinum catalyst |
| | | mass (parts by mass) | 0.01 | 0.01 |
| | | of additive in 100 parts | | |
| | | by mass of silicone | | |
| | | resin layer | | |

| evaluation condition | | 400° C.-1 h | 400° C.-1 h |
|---|---|---|---|
| evaluation result | length of end portion | 0.0 mm | 2.0 mm |
| | degradation | | |

As shown in Table 5, it was confirmed that the laminate (Example 21) of the present invention showed an advantageous effect in spite of evaluation at 400° C. as compared with the laminate (Example 22) which did not satisfy the requirements of the present invention because the silicone resin layer did not contain any specified element.

In the following examples 23 to 28, description will be made about examples in which a resin laminate was manufactured using, as a substrate, a polyimide resin substrate which was a resin substrate.

A polyimide film (0.038 mm thick, the trade name “XENOMAX” manufactured by Toyobo Co., Ltd.) was used as the polyimide resin substrate.

### Example 23

A resin laminate having a support substrate, a silicone resin layer and a polyimide resin substrate arranged in this order was obtained in the same procedure as in Example 6, except that the polyimide resin substrate was used in place of the glass substrate.

### Example 24

A resin laminate having a support substrate, a silicone resin layer and a polyimide resin substrate arranged in this order was obtained in the same procedure as in Example 18, except that the polyimide resin substrate was used in place of the glass substrate.

### Example 25

The composition Y prepared in the same manner as in Example 18 was applied to a polyimide resin substrate by a die coating method so that the thickness of the silicone resin layer after curing could achieve 8 μm. Heating treatment was performed at 140° C. for 10 minutes by use of a hot plate. Thus, a coating film was formed.

Next, heating treatment was performed at 220° C. for 30 minutes on the polyimide resin substrate where the coating film had been formed. Thus, a silicone resin layer was formed.

Next, a support substrate was placed on the silicone resin layer, and bonded to each other by use of a roll laminator. Thus, a resin laminate was obtained.

### Example 26

A resin laminate was obtained in the same procedure as in Example 23, except that no predetermined metal compound was used. Incidentally, the silicone resin layer of the resin laminate in Example 26 did not contain any specified element.

### Example 27

A resin laminate was obtained in the same procedure as in Example 24, except that no predetermined metal compound was used, the temperature of 140° C. was changed to 100° C., and the temperature of 220° C. was changed to 250° C. Incidentally, the silicone resin layer of the resin laminate in Example 27 did not contain any specified element.

### Example 28

A resin laminate was obtained in the same procedure as in Example 25, except that no predetermined metal compound was used, the temperature of 140° C. was changed to 100° C., and the temperature of 220° C. was changed to 250° C. Incidentally, the silicone resin layer of the resin laminate in Example 28 did not contain any specified element.

### [Evaluation of End Portion Degradation]

The resin laminate obtained in each example was cut out to obtain a sample measuring 50 mm by 50 mm. Each sample thus obtained was put into an electric furnace preheated to 400° C. or 450° C. Heating treatment for one hour was performed, and the sample was then taken out. The atmosphere in the electric furnace was an air atmosphere.

An end portion of the taken-out sample was observed by a microscope to observe a maximum length of a whitened part from the edge of the end portion. The maximum length means a maximum value of length L of the whitened end portion as shown in FIG. 3. The shorter the length L expressing the end portion degradation is, the more excellent the effect is.

The results are shown collectively in Table 6.

The field “formation surface” in Table 6 shows which the silicone resin layer was formed on the surface of the support substrate or on the surface of the polyimide resin substrate before the resin laminate was manufactured.

The field “evaluation condition” shows the temperature and time with which evaluation was made in the evaluation of the end portion degradation.

In addition, “400° C.-1 h and 450° C.-1 h” in the field “evaluation condition” of Example 24 and Example 25 shows that the “length of the end portion degradation” was “0.0 mm” either the condition was “400° C.-1 h” or “450° C.-1 h”.

TABLE 6

| | | | | | | | Example | Example |
|---|---|---|---|---|---|---|---|---|
| | | | Example 23 | Example 24 | Example 25 | Example 26 | 27 | 28 |
| composition | kind of curable silicone | | curable silicone 1 | curable silicone 2 | curable silicone 2 | curable silicone 1 | curable | curable |
| | | | | | | | silicone 2 | silicone 2 |
| | metal | kind | tris (2,4- | tris (2- | tris (2- | | | |
| | compound 1 | | pentanedionato) | ethylhexanoate) | ethylhexanoate) | | | |
| | | | iron (III) | iron (III) | iron (III) | | | |
| | | kind of | Fe | Fe | Fe | | | |
| | | metal | | | | | | |
| | | mass (parts | 0.047 | 0.098 | 0.098 | | | |
| | | by mass) of | | | | | | |
| | | metal | | | | | | |
| | | element in | | | | | | |
| | | 100 parts | | | | | | |
| | | by mass of | | | | | | |
| | | silicone | | | | | | |
| | | resin layer | | | | | | |
| | metal | kind | zirconium tetra-n- | zirconium tetra-n- | zirconium tetra-n- | | | |
| | compound 2 | | propoxide | propoxide | propoxide | | | |
| | | kind of | Zr | Zr | Zr | | | |
| | | metal | | | | | | |
| | | mass (parts | 0.075 | 0.392 | 0.392 | | | |
| | | by mass) of | | | | | | |
| | | metal | | | | | | |
| | | element in | | | | | | |
| | | 100 parts | | | | | | |
| | | by mass of | | | | | | |
| | | silicone | | | | | | |
| | | resin layer | | | | | | |
| | additive | kind | bis (2- | platinum catalyst | platinum catalyst | bis (2- | platinum | platinum |
| | | | ethylhexanoate) | | | ethylhexanoate) | catalyst | catalyst |
| | | | tin (II) | | | tin (II) | | |
| | | mass (parts | 0.59 | 0.01 | 0.01 | 0.59 | 0.01 | 0.01 |
| | | by mass) of | | | | | | |
| | | additive in | | | | | | |
| | | 100 parts | | | | | | |
| | | by mass of | | | | | | |
| | | silicone | | | | | | |
| | | resin layer | | | | | | |

| formation surface | | support substrate | support substrate | polyimide resin | support substrate | support | polyimide |
|---|---|---|---|---|---|---|---|
| | | | | substrate | | substrate | resin |
| | | | | | | | substrate |
| evaluation condition | | 450° C.-1 h | 400° C.-1 h and | 400° C.-1 h and | 450° C.-1 h | 400° C.-1 h | 400° C.-1 h |
| | | | 450° C.-1 h | 450° C.-1 h | | | |
| evaluation result | length of | 0.0 mm | 0.0 mm | 0.0 mm | 3.0 mm | 2.0 mm | 2.0 mm |
| | end portion | | | | | | |
| | degradation | | | | | | |

As shown in Table 6, it was confirmed that each laminate according to the present invention showed a desired effect even when the substrate was replaced by a resin substrate.

In addition, it was confirmed that the laminate according to the present invention showed a desired effect even when the silicone resin layer was formed on the surface of the resin substrate to manufacture the resin laminate.

On the other hand, in Examples 26 to 28 in which the silicone resin layer did not contain any specified element, the effect was inferior.

### Example 29

A laminate is manufactured, in which a Si wafer having a diameter of 150 mm and a thickness of 625 μm is bonded in place of the glass substrate having a length of 240 mm, a width of 240 mm and a thickness of 0.2 mm in Example 18. For this laminate, evaluation of end portion degradation is made on the same conditions as in Example 18. The length of the end portion degradation is 0.0 mm.

### Example 30

A laminate is manufactured, in which a Si wafer having a diameter of 150 mm and a thickness of 625 μm is bonded in place of the glass substrate having a length of 240 mm, a width of 240 mm and a thickness of 0.2 mm in Example 20. For this laminate, evaluation of end portion degradation is made on the same conditions as in Example 20. The length of the end portion degradation is 3.0 mm.

In each of the resin laminates obtained in Examples 23 to 28, the support substrate and the polyimide resin substrate adhered to the silicone resin layer without generating bubbles, and no distortion defect was observed.

In addition, in the resin laminate in each example, the peel strength in the interface between the silicone resin layer and the layer of the support substrate was larger than the peel strength in the interface between the layer of the polyimide resin substrate and the silicone resin layer before and after the evaluation of the end portion degradation. A stainless steel blade with 0.1 mm thick was inserted into the interface between the polyimide resin substrate and the silicone resin layer in each of the resin laminates in Examples 23 to 25 so as to form a trigger portion for peeling. After that, the polyimide resin substrate was fully fixed, and the support substrate was raised to peel off the polyimide resin substrate. As a result, it was confirmed that the silicone resin layer did not adhere to the peeled polyimide resin substrate.

In addition, in the laminate in Example 29, where the Si wafer is laminated, the silicone resin layer and the Si wafer adhere to each other without generating bubbles, and no distortion defect is observed. In addition, a stainless steel blade 0.1 mm thick is inserted into the interface between the Si wafer and the silicone resin layer in Example 29 so as to form a trigger portion for peeling. After that, the Si wafer is fully fixed, and the support substrate is raised to peel off the Si wafer. As a result, it is confirmed that the silicone resin layer does not adhere to the peeled Si wafer.

The present application is based on Japanese Patent Application No. 2016-255155 filed on Dec. 28, 2015, Japanese Patent Application No. 2017-120816 filed on Jun. 20, 2017, and Japanese Patent Application No. 2017-186225 filed on Sep. 27, 2017, the contents of which are incorporated herein by reference.

### DESCRIPTION OF REFERENCE NUMERALS AND SIGNS

10,100 glass laminate
12 support substrate
14 silicone resin layer
14a surface of the silicone resin layer 14
16 glass substrate
16a first main surface of the glass substrate 16
16b second main surface of the glass substrate 16
18 resin layer-attached support substrate
electronic device member
22 electronic device member-attached laminate
24 member-attached glass substrate
102 end portion
L length of end portion degradation

1. A laminate, comprising:
a support substrate; a silicone resin layer; and a substrate arranged in this order,
wherein the silicone resin layer comprises at least one metal element selected from the group consisting of a 3d transition metal, a 4d transition metal, a lanthanide metal, and bismuth.

2. The laminate according to claim 1, wherein the silicone resin layer comprises at least one metal element selected from the group consisting of a 3d transition metal, a lanthanide metal, and bismuth.

3. The laminate according to claim 1, wherein the silicone resin layer comprises at least one metal element selected from the group consisting of iron, manganese, copper, cerium, cobalt, nickel, chromium, and bismuth.

4. The laminate according to claim 1, wherein the silicone resin layer comprises at least one metal element selected from the group consisting of iron, manganese, copper, cerium, and bismuth.

5. The laminate according to claim 1, wherein a plurality of the substrates are laminated on the support substrate through the silicone resin layer.

6. The laminate according to claim 1, wherein the substrate is a glass substrate.

7. The laminate according to claim 1, wherein the substrate is a resin substrate.

8. The laminate according to claim 7, wherein the resin substrate is a polyimide resin substrate.

9. The laminate according to claim 1, wherein the substrate is a substrate comprising a semiconductor material.

10. The laminate according to claim 9, wherein the semiconductor material is Si, SiC, GaN, gallium oxide, or diamond.

11. A silicone resin layer-attached support substrate, comprising:
a support substrate and a silicone resin layer arranged in this order, wherein the silicone resin layer comprises at least one metal element selected from the group consisting of a 3d transition metal, a 4d transition metal, a lanthanide metal, and bismuth.

12. A method for manufacturing an electronic device, the method comprising:
forming an electronic device member on a surface of the substrate of the laminate according to claim 1, to obtain an electronic device member-attached laminate; and
removing a silicone resin layer-attached support substrate which comprises the support substrate and the silicone resin layer, from the electronic device member-attached laminate, to obtain an electronic device comprising the substrate and the electronic device member.

13. A silicone rein layer-attached resin substrate, comprising:
a resin substrate and a silicone resin layer arranged in this order,
wherein the silicone resin layer comprises at least one metal element selected from the group consisting of a 3d transition metal, a 4d transition metal, a lanthanide metal, and bismuth.

14. A method for manufacturing an electronic device, the method comprising:
forming a laminate using the silicone resin layer-attached resin substrate according to claim 13, and a support substrate;
forming an electronic device member on a surface of the resin substrate of the laminate, to obtain an electronic device member-attached laminate; and
removing the support substrate and the silicone resin layer from the electronic device member-attached laminate, to obtain an electronic device comprising the resin substrate and the electronic device member.
